(19) United States
(12) Patent Application Publication
(10) Pub. No.: US 2024/0321715 A1
(43) Pub. Date: Sep. 26, 2024

(54) PRINTED CIRCUIT BOARD AND SEMICONDUCTOR PACKAGE INCLUDING THE SAME

(71) Applicant: Samsung Electronics Co., Ltd., Suwon-si (KR)

(72) Inventor: Hyejin Kim, Suwon-si (KR)

(21) Appl. No.: 18/613,414

(22) Filed: Mar. 22, 2024

(30) Foreign Application Priority Data
Mar. 24, 2023 (KR) 10-2023-0038962
May 10, 2023 (KR) 10-2023-0060704

(51) Int. Cl. H01L 23/498; H01L 23/00; H05K 1/11

(52) U.S. Cl. CPC H01L 23/49838; H01L 23/49822; H05K 1/113; H01L 24/16; H01L 2224/16227; H05K 2201/09445; H05K 2201/09481

(57) ABSTRACT

A printed circuit board includes a board base including a plurality of base layers, a plurality of via pads with a via pad being disposed on each of the plurality of base layers, and a plurality of through-vias with at least one respective through-via of the plurality of through-vias penetrating a respective base layer and making contact with a respective via pad of the plurality of base layers. Each via pad of the plurality of via pads has a shape in which a plurality of sub-shapes are arranged based on the center point of the respective via pad in a partially overlapping manner, and a group of through-vias are in contact with a respective via pad in a manner corresponding to the plurality of sub-shapes.

### CROSS-REFERENCE TO RELATED APPLICATION

This application is based on and claims priority under 35 U.S.C. § 119 to Korean Patent Application No. 10-2023-0038962, filed on Mar. 24, 2023, in the Korean Intellectual Property Office, and Korean Patent Application No. 10-2023-0060704, filed on May 10, 2023, in the Korean Intellectual Property Office, the disclosures of which are incorporated by reference herein in their entireties.

### BACKGROUND

The inventive concept relates to a printed circuit board and a semiconductor package including the printed circuit board, and more particularly, to a printed circuit board including via pads, and a semiconductor package including the printed circuit board.

Recently, in the electronic product market, demand for portable devices has rapidly increased, and as a result, small and light-weight electronic components are required for such electronic products. To reduce the size and weight of electronic components, semiconductor packages included in electronic components are required to have a small volume and high data processing capacity. In such a semiconductor package, semiconductor chips are mounted on a printed circuit board. Thus, for the reliability of products, it is very important to accurately detect defects of a printed circuit board of a semiconductor package and provide solutions therefor.

### SUMMARY

The inventive concept provides a printed circuit board guaranteeing electrical reliability and high thermal conductivity between a semiconductor chip and a printed circuit board, and a semiconductor package including the printed circuit board.

Embodiments of the inventive concept are not limited to those mentioned above, and the inventive concept will be apparently understood by those skilled in the art through the following description.

According to an aspect of the inventive concept, a printed circuit board includes base layers are stacked in a vertical direction from a lowermost layer to an uppermost layer, traces disposed on a first base layer of the plurality of base layers, via pads with each via pad respectively disposed on a respective base layer of the base layers and electrically connected to the traces, and through-vias with each through-via extending in the vertical direction through a respective base layer of the base layers to electrically connect a respective first via pad of the via pads to a respective second via pad of the vi pads, wherein the respective first via pad and the respective second via pad are positioned at different vertical levels. Each of the via pads has a shape comprising at least two sub-shapes having the same dimensions and that are arranged around a center point of a respective via pad in a partially overlapping manner with regular angular spacing between adjacent sub-shapes, and each of the via pads is in contact with at least two of the respective through-vias.

According to another aspect of the inventive concept, there is provided a printed circuit board including a board base including a plurality of base layers, a plurality of via pads with a via pad being disposed on each of the plurality of base layers, and a plurality of through-vias with at least one respective through-via of the plurality of through-vias penetrating a respective base layer and making contact with a respective via pad of the plurality of base layers. Each via pad of the plurality via pads has a shape in which a plurality of sub-shapes are arranged based on a center point of the respective via pad in a partially overlapping manner, and a group of through-vias are in contact with the respective via pad in a manner corresponding to the plurality of sub-shapes.

According to another aspect of the inventive concept, there is provided a semiconductor package including a printed circuit board, a semiconductor chip, and a connection member. The printed circuit board includes a chip mounting region and a peripheral region planarly surrounding the chip mounting region. The semiconductor chip has first and second surfaces facing each other and include a chip pad disposed on the first surface. The semiconductor chip is mounted in the chip mounting region with the first surface facing an upper surface of the printed circuit board. The connection member is attached to the chip pad. The printed circuit board includes a plurality of base layers, via pads with each via pad respectively disposed on a respective base layer of the plurality of base layers and electrically connected to a plurality of traces, and through-vias extending in a vertical direction with each of the through-vias extending through a respective base layer of the plurality of base layers to electrically connect the via pads positioned at different vertical levels. Each of the via pads has a shape in which at least two sub-shapes have the same dimension and are arranged around the center point of the via pad at in a partially overlapping manner with regular angular spacing between adjacent sub-shapes, and each of the via pads are in contact with at least two respective through-vias.

### BRIEF DESCRIPTION OF THE DRAWINGS

Embodiments will be more clearly understood from the following detailed description taken in conjunction with the accompanying drawings in which:

FIG. 1 is a perspective view schematically illustrating a main board including a semiconductor package according to an embodiment;

FIG. 2 is a perspective view illustrating a semiconductor package including a printed circuit board according to an embodiment;

FIG. 3 is a cross-sectional view illustrating a printed circuit board according to an embodiment;

FIG. 4 is an enlarged plan view illustrating region AA of FIG. 3;

FIG. 5 is an enlarged perspective view illustrating region AA of FIG. 3;

FIG. 6 is a cross-sectional view illustrating a semiconductor package according to an embodiment;

FIG. 7 is an enlarged plan view illustrating BB region of FIG. 6;

FIG. 8 is an enlarged cross-sectional view illustrating region CC of FIG. 6;

FIGS. 9 to 11 are plan views illustrating portions of printed circuit boards according to other embodiments;

FIG. 12 is a flowchart illustrating a printed circuit board test process according to an embodiment;

FIG. 13 is a block diagram illustrating a removable storage device;

FIGS. 14 and 15 are views illustrating various examples of form factors specifying printed circuit boards that are usable in the removable storage device shown in FIG. 13; and

FIG. 16 is a plan view illustrating a printed circuit board according to another embodiment.

### DETAILED DESCRIPTION OF THE EMBODIMENTS

Hereinafter, embodiments will be described with reference to the accompanying drawings, in which various embodiments are shown. The invention may, however, be embodied in many different forms and should not be construed as limited to the example embodiments set forth herein. These example embodiments are just that—examples—and many implementations and variations are possible that do not require the details provided herein. It should also be emphasized that the disclosure provides details of alternative examples, but such listing of alternatives is not exhaustive. Furthermore, any consistency of detail between various examples should not be interpreted as requiring such detail—it is impracticable to list every possible variation for every feature described herein. The language of the claims should be referenced in determining the requirements of the invention.

In the drawings, the size and relative sizes of layers and regions may be exaggerated for clarity. Like numbers refer to like elements throughout. Though the different figures show variations of exemplary embodiments, these figures are not necessarily intended to be mutually exclusive from each other. Rather, as will be seen from the context of the detailed description below, certain features depicted and described in different figures can be combined with other features from other figures to result in various embodiments, when taking the figures and their description as a whole into consideration.

The terminology used herein is for the purpose of describing particular embodiments only and is not intended to be limiting of the invention. Items described in the singular herein may be provided in plural, as can be seen, for example, in the drawings. Thus, the description of a single item that is provided in plural should be understood to be applicable to the remaining plurality of items unless context indicates otherwise. Additionally, unless otherwise indicated, when describing relationships between groups of items, it will be understood that such relationships exist for individual items within each group and the relationship does not require every member of the group to have the relationship. For example, the relationship between the groups may include one to one relationships, one to many relationships, and/or many to one relationships for at least one member of each group. For example, a first group of items connected to a second group of items indicates that at least one item of the first group is connected to at least one item of the second group. Thus, when a first group is connected to a second group, there may be items in the first group connected to every item in the second group, connected to a subset of items in the second group, or not connected to any items in the second group. Details of a relationship will be apparent from the figures referenced in describing the relationship.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” share a common electrical node through electrical connections by one or more conductors, such as, for example, wires, pads, internal electrical lines, through-vias, etc. As such, directly electrically connected components do not include components electrically connected through active elements, such as transistors or diodes.

Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

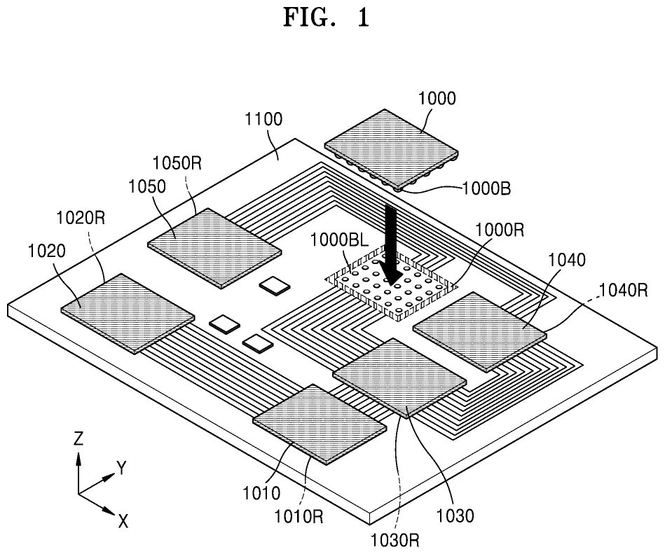

FIG. 1 is a perspective view schematically illustrating a main board 1100 including a semiconductor package 10 according to some embodiments.

Referring to FIG. 1, the main board 1100 may include various pieces of hardware mounted on an upper surface thereof.

The various pieces of hardware included in the main board 1100 may each be mounted in a dedicated region. For example, the main board 1100 may include a dedicated region 1000R for a storage device 1000, a dedicated region 1010R for a host 1010, a dedicated region 1020R for a memory 1020, a dedicated region 1030R for a chipset 1030, a dedicated region 1040R for a graphics processing unit 1040, and a dedicated region 1050R for a network module 1050. The dedicated regions 1000R, 1010R, 1020R, 1030R, 1040R, and 1050R may be electrically connected to each other through various wires and/or traces provided on the main board 1100.

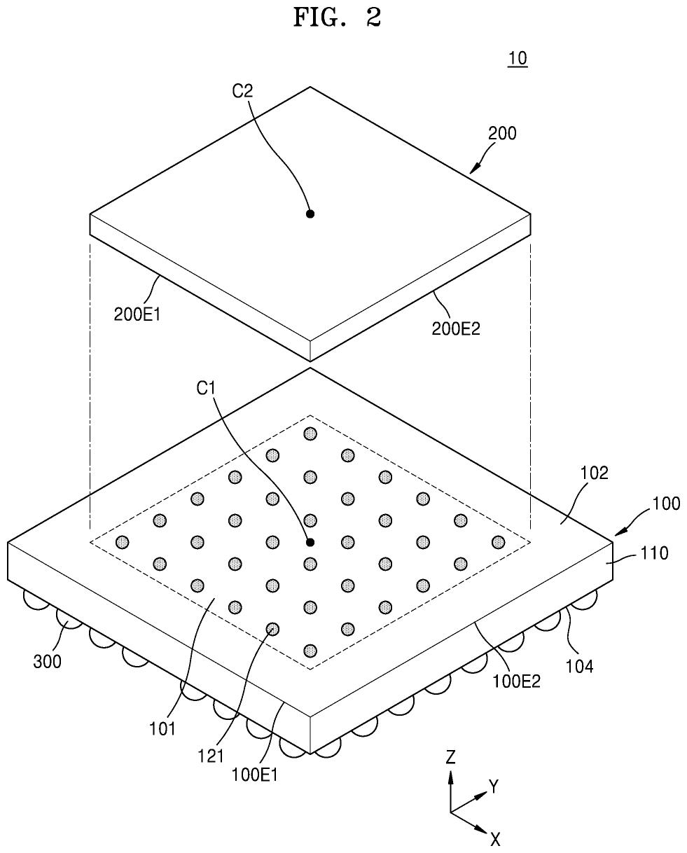

In some embodiments, the storage device 1000, the host 1010, the memory 1020, the chipset 1030, the graphics processing unit 1040, and/or the network module 1050 may each be provided as a ball grid array (BGA)-type semiconductor package, such as semiconductor package 10 (refer to FIG. 2). For example, the storage device 1000 may include solder balls 1000B as external connection terminals, and the storage device 1000 may be mounted on the main board 1100 such that the solder balls 1000B may be respectively coupled to ball lands 1000BL arranged in the dedicated region 1000R. The storage device 1000 may be mounted on the main board 1100 using a surface mounting technique.

One or a plurality of storage devices 1000 may be provided on the main board 1100. In some embodiments, storage devices 1000 may be mounted on different surfaces of the main board 1100. For example, a storage device 1000 may be mounted on the upper surface of the main board 1100, and another storage device 1000 may be mounted on a lower surface of the main board 1100.

The storage device 1000 may transmit program code to the host 1010 according to a sideband protocol. In some embodiments, the sideband protocol may include a communication protocol for normal operations and may further include additional communication protocols such as Inter-Integrated Circuit (I2C), Management Component Transport Protocol (MCTP), or System Management Bus (SMBus). Components of the storage device 1000 are described later.

FIG. 2 is a perspective view illustrating a semiconductor package 10 including a printed circuit board 100 according to an embodiment.

Referring to FIG. 2, the semiconductor package 10 may include the printed circuit board 100 and a semiconductor chip 200.

The printed circuit board 100 may be a package board. The printed circuit board 100 may include a board base 110, upper connection pads 121 provided on an upper surface 102 of the printed circuit board 100, and lower connection pads (not shown) provided on a lower surface 104 of the printed circuit board 100.

The board base 110 may form the exterior of the printed circuit board 100 and may be formed of and/or include, for example, at least one material selected from the group consisting of a phenol resin, an epoxy resin, and polyimide. Internal interconnection structures (for example, via pads, through-vias, traces, or the like) may be provided in the board base 110 to electrically connect the upper connection pads 121 and the lower connection pads (not shown) to each other. The upper connection pads 121 may be connected to conductive connection structures (not shown) provided on a lower surface of the semiconductor chip 200, and the lower connection pads (not shown) may be respectively connected to solder balls 300 which are external connection terminals.

The printed circuit board 100 may include a mounting region 101 in which the semiconductor chip 200 is mounted. The mounting region 101 is a region in which the semiconductor chip 200 is disposed, and the mounting region 101 and the semiconductor chip 200 may substantially overlap each other in a vertical direction (Z direction). Because the mounting region 101 overlaps the semiconductor chip 200 in the vertical direction (Z direction), the mounting region 101 may have the same shape and size as the semiconductor chip 200 in a horizontal plane.

In addition, a first horizontal direction (X direction) may be defined as a direction parallel to a first end 200E1 of the semiconductor chip 200 (e.g., parallel to a horizontal edge of the first end 200E1 of the semiconductor chip 200), and a second horizontal direction (Y direction) may be defined as a direction parallel to a second end 200E2 of the semiconductor chip 200 (e.g., parallel to a horizontal edge of the second end 200E1 of the semiconductor chip 200). In some embodiments, a center point C1 of the mounting region 101 and a center point C2 of the semiconductor chip 200 may coincide with each other on a plane parallel to the first horizontal direction (X direction) and the second horizontal direction (Y direction) (e.g., may be vertically coincident).

In addition, the width of the semiconductor chip 200 in the first horizontal direction (X direction) may be substantially the same as the width of the mounting region 101 in the first horizontal direction (X direction), and the width of the semiconductor chip 200 in the second horizontal direction (Y direction) may be substantially the same as the width of the mounting region 101 in the second horizontal direction (Y direction).

In some embodiments, the semiconductor chip 200 may be mounted in the mounting region 101 of the printed circuit board 100 by a flip chip method. For example, the semiconductor chip 200 may be connected to the upper connection pads 121 of the printed circuit board 100 through the conductive connection structures (not shown) such as solder bumps but embodiments are not limited thereto. For example, in other embodiments, the semiconductor chip 200 may be mounted in the mounting region 101 of the printed circuit board 100 through bonding wires.

The semiconductor chip 200 may be a logic chip or a memory chip. For example, the memory chip may be a volatile memory chip such as a dynamic random access memory (DRAM) chip or a static random access memory (SRAM) chip, or may be a nonvolatile memory chip such as a phase-change RAM (PRAM) chip, a magnetoresistive RAM (MRAM) chip, a ferroelectric RAM (FeRAM) chip, or a resistive RAM (RRAM) chip. In addition, the logic chip may be, for example, a microprocessor, an analog device, a digital signal processor, or an application processor.

Although FIG. 2 illustrates that the semiconductor package 10 includes one semiconductor chip 200, the semiconductor package 10 may include a plurality of semiconductor chips 200. In some embodiments, the semiconductor chip 200 may be a chip stack in which a plurality of semiconductor chips 200 are vertically stacked. For example, the semiconductor chip 200 may be a high bandwidth memory (HBM) chip.

A center point C1 of the printed circuit board 100 may coincide with the center point C1 of the mounting region 101 and/or the center point C2 of the semiconductor chip 200 on a plane parallel to the first horizontal direction (X direction) and the second horizontal direction (Y direction) (e.g., may be vertically coincident). An end of the printed circuit board 100 adjacent to the first end 200E1 of the semiconductor chip 200 may be defined as a first end 100E1 of the printed circuit board 100, and an end of the printed circuit board 100 that is opposite the first end 100E1 of the printed circuit board 100 may be defined as a second end 100E2 of the printed circuit board 100. The center point C1 of the printed circuit board 100 may be substantially equidistant from the first and second ends 100E1 and 100E2 of the printed circuit board 100.

In addition, although not shown in FIG. 2, an underfill may be arranged between the printed circuit board 100 and the semiconductor chip 200. For example, the underfill may be formed through an underfill process to fill a gap between the printed circuit board 100 and the semiconductor chip 200. The underfill may be filled between the printed circuit board 100 and the semiconductor chip 200 and may surround the conductive connection structures (not shown) arranged between the printed circuit board 100 and the semiconductor chip 200.

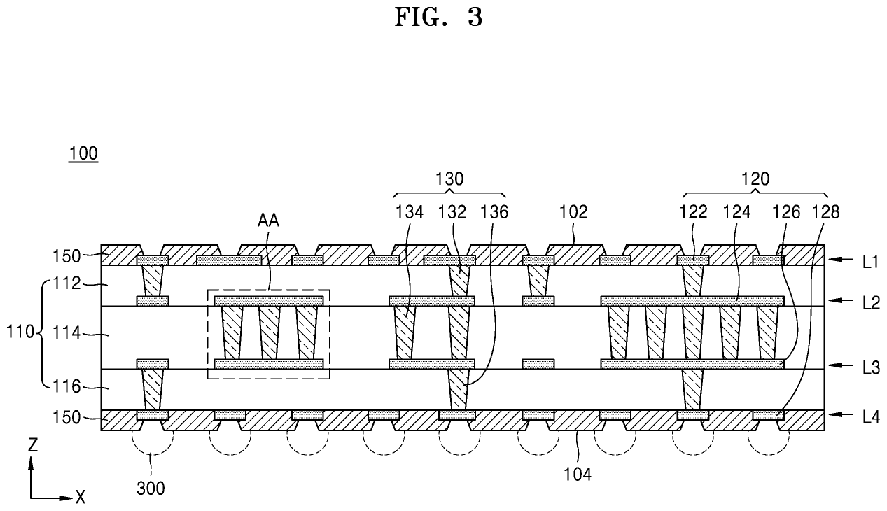

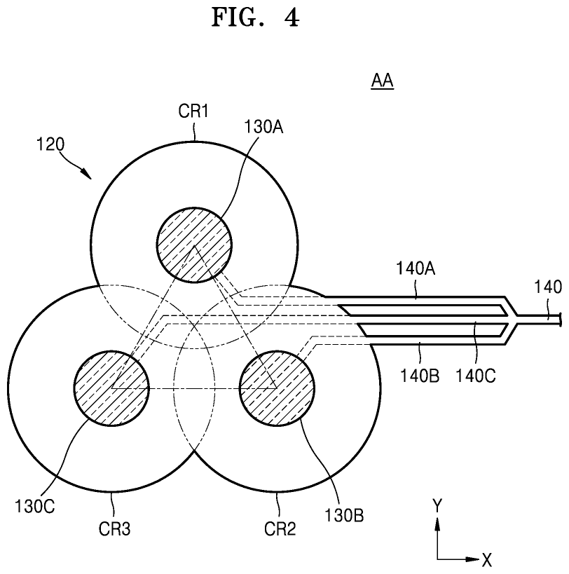

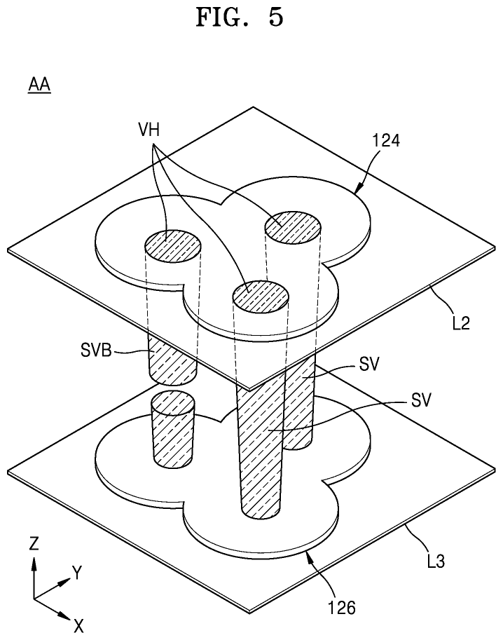

FIG. 3 is a cross-sectional view illustrating the printed circuit board 100 according to an embodiment, FIG. 4 is an enlarged plan view illustrating region AA of FIG. 3, and FIG. 5 is an enlarged perspective view illustrating region AA of FIG. 3.

Referring to FIGS. 3 to 5, the printed circuit board 100 may include the board base 110, via pads 120, and first to fourth wiring layers L1, L2, L3, and L4.

The printed circuit board 100 may include the board base 110 which may include at least two base layers. For example, the board base 110 may include K base layers 112, 114, and 116 (where K refers to an integer greater than 1) which may be stacked in the vertical direction from a lowermost layer (first layer) to an uppermost layer (Kth layer). In addition, the printed circuit board 100 may include: the via pads 120, which are disposed on the base layers such as base layers 112, 114, and 116, traces 140 disposed on the base layers 112, 114, and 116 and which are electrically connected to traces 140; and through-vias 130 that extend in the vertical direction through the base layers such as base layers 112, 114, and 116, and which electrically connect via pads 120 positioned at different vertical levels to each other. For example, referring to FIG. 3, through-via 134 may connect a first via pad disposed at a lower surface of base layer 114 to a second via pad disposed at an upper surface of base layer 114.

As shown in the example of FIG. 3, the board base 110 may be formed by stacking three base layers 112, 114, and 116. The first to fourth wiring layers L1, L2, L3, and L4 may be arranged on upper and lower surfaces of the three base layers 112, 114, and 116. Here, for case of description, three base layers 112, 114, and 116 are illustrated. However, the number of base layers and the number of wiring layers of the board base 110 in embodiments are not limited thereto.

In embodiments where the board base 110 is formed by stacking the base layers 112, 114, and 116 (first to third base layers 112, 114, and 116), among the first to fourth wiring layers L1, L2, L3, and L4, the first wiring layer L1 may be disposed on an upper surface of the first base layer 112, the second wiring layer L2 may be disposed between a lower surface of the first base layer 112 and an upper surface of the second base layer 114, the third wiring layer L3 may be disposed between a lower surface of the second base layer 114 and an upper surface of the third base layer 116, and the fourth wiring layer L4 may be disposed on a lower surface of the third base layer 116.

The first to fourth wiring layers L1, L2, L3, and L4 may include the via pads 120. For example, the first wiring layer L1 may include first via pads 122, the second wiring layer L2 may include second via pads 124, the third wiring layer L3 may include third via pads 126, and the fourth wiring layer L4 may include fourth via pads 128. Here, the first via pads 122 may correspond to the upper connection pads 121 (refer to FIG. 2).

Each of the first to fourth via pads 122, 124, 126, and 128 may be formed of and/or include a conductive material. In some embodiments, each of the first to fourth via pads 122, 124, 126, and 128 may be formed of and/or include a metal. In some embodiments, the first to fourth via pads 122, 124, 126, and 128 of the first to fourth wiring layers L1, L2, L3, and L4 may be formed of and/or include similar or the same material. The first to fourth via pads 122, 124, 126, and 128 may be formed by a plating method. For example, the first to fourth via pads 122, 124, 126, and 128 may be formed of and/or include copper (Cu), nickel (Ni), and/or gold (Au) but embodiments are not limited thereto.

The through-vias 130 electrically connecting the first to fourth via pads 122, 124, 126, and 128 to each other in the vertical direction (Z direction) may be formed in the board base 110. In some embodiments, the through-vias 130 may be formed of and/or include copper (Cu), nickel (Ni), and/or beryllium copper. The plurality of through-vias 130 may include first through-vias 132 penetrating the first base layer 112, second through-vias 134 penetrating the second base layer 114, and third through-vias 136 penetrating the third base layer 116.

A solder resist layer 150 may be formed on the upper surface of the board base 110 to cover at least portions of the first via pads 122. In addition, another solder resist layer 150 may be formed on the lower surface of the board base 110 to cover at least portions of the fourth via pads 128. Portions of the first via pads 122 and portions of the fourth via pad 128 that are exposed and not covered by the solder resist layers 150 may respectively form upper connection pads and lower connection pads of the printed circuit board 100. Although not shown in FIGS. 3 to 5, each of upper surfaces of the upper connection pads and the lower connection pads may include an organic solderability preservative (OSP) coating.

The semiconductor chip 200 (refer to FIG. 2) may be mounted on the upper surface 102 of the printed circuit board 100. That is, the upper surface 102 of the printed circuit board 100 may be a chip mounting surface. In addition, the solder balls 300 that are external connection terminals may be attached to the lower surface 104 of the printed circuit board 100. The lower surface 104 of the printed circuit board 100 may be a connection terminal attachment surface. The semiconductor chip 200 (refer to FIG. 2) may be electrically connected to the first via pads 122 that are upper connection pads. In addition, the solder balls 300 may be electrically connected to the fourth via pads 128 that are lower connection pads.

Recently, in the electronic product market, demand for portable devices has rapidly increased, and as a result, electronic components to be mounted on electronic products are constantly required to be small and light. Semiconductor packages (such as the semiconductor package 10 shown in FIG. 2) to be mounted on electronic components are required to have a small volume and high data processing capacity for size and weight reduction. Because the semiconductor chip 200 (refer to FIG. 2) of the semiconductor package 10 (refer to FIG. 2) is mounted on the printed circuit board 100, the reliability of the semiconductor package 10 may be improved by accurately detecting defects of the printed circuit board 100 of the semiconductor package 10 and deriving solutions for the defects.

Moreover, the through-vias 130 are used to connect circuits to each other in the vertical direction (Z direction) from the upper surface 102 of the printed circuit board 100 to the lower surface 104 of the printed circuit board 100. In the printed circuit board 100, the number of through-vias 130 provided between the base layers 112, 114, and 116 is proportional to the number of base layers 112, 114, and 116, and the number of through-vias 130 is determined according to the degree of integration of circuits.

Recently, small vias SV having a relatively small diameter are used as the through-vias 130 when it is difficult to manufacture the printed circuit board 100 because of a high degree of circuit integration. In general, a through-via having a diameter of 10 μm or less may be referred to as a small via SV. However, embodiments are not limited thereto.

printed circuit boards having small vias SV, a defect rate may increase during the process of forming small vias SV compared to the case of forming general through-vias. In addition, because small vias SV have a smaller volume than general through-vias, the small vias SV have relatively low performance as paths for heat generated in the semiconductor chip 200 (refer to FIG. 2), and thus, issues regarding heat dissipation from the semiconductor chip 200 (refer to FIG. 2) may occur.

To address these issues, each of the via pads 120 of the printed circuit board 100 of the inventive concept may have a shape in which N (where N refers to an integer of 2 or greater) sub shapes CR1, CR2, and CR3 having the same dimensions are arranged around a center point of the via pad 120 with regular angular spacing between adjacent sub shapes (for example, each of the sub-shapes may be congruent with one another and the angular spacing of a center point of each sub-shape from the center point of an adjacent sub-shape may be the same, such as 120° from each other in a clockwise direction) in an overlapping manner (e.g., the center point of the via pad 120 may be on or within an outer boundary of each sub-shape such). In the embodiments shown in the figures, the sub-shapes are circle shapes, and the dimension that is the same is the diameter of the circle shapes, but embodiments are not limited thereto. In such embodiments, the distance from the center point of the via pad 120 may be less than or equal to the radius of the circle shape and the distance between centers of adjacent circle shapes may be less than the diameter of the circle shapes. In other embodiments the sub-shapes may be triangles, squares, ovals, polygons, and the like.

As shown in the example of FIG. 4, the via pads 120 may be designed such that two to N through-vias 130A, 130B, and 130C may be in contact with one via pad 120. In some embodiments, via holes VH may respectively be formed at center points of the sub-shapes CR1, CR2, and CR3, and the through-vias 130A, 130B, and 130C may respectively be provided in the via holes VH. However, the number of sub-shapes CR1, CR2, and CR3 and the number of through-vias 130A, 130B, and 130C do not have to be equal to each other. For example, one via pad 120 may include three sub-shapes CR1, CR2, and CR3, and only two of the through-vias 130A, 130B, and 130C may be in contact with the via pad 120. In any of the cases, one via pad 120 may be in contact with a plurality of through-vias.

In addition, a plurality of traces 140 may be connected to one via pad 120. In some embodiments, as many traces 140A, 140B, and 140C as the number of through-vias 130A, 130B, and 130C may be connected to one via pad 120, and the through-vias 130A, 130B, and 130C and the traces 140A, 140B, and 140C may be matched to each other (e.g., for each via pad there may be a corresponding through-via). In addition, the traces 140A, 140B, and 140C may be designed to be in contact with an outer surface of the via pad 120, and the through-vias 130A, 130B, and 130C may be matched to the traces 140A, 140B, and 140C in a 1:1 positional relationship. This is shown by dashed lines in FIG. 4.

In some embodiments, the center points of the sub-shapes CR1, CR2, and CR3 of one via pad 120 may correspond to vertices of an imaginary regular N-polygon (where N is an integer greater than or equal to 3) or to endpoints of an imaginary line segment, and the center point of the via pad 120 may correspond to the geometric center of the imaginary regular N-polygon or imaginary line segment. For example, as shown in FIG. 4, the center points of the sub-shapes CR1, CR2, and CR3 may correspond to the vertices of an imaginary equilateral triangle.

For example, each of the through-vias 130A, 130B, and 130C may be a small via SV having a diameter of about 10 μm or less, and the maximum diameter of each via pad 120 may be from 10 μm to 50 μm. However, embodiments are not limited to small vias SV and via pads having these dimensions. In some embodiments, two to ten sub-shapes CR1, CR2, and CR3 may be arranged based on the center point of each via pad 120.

Therefore, according to the printed circuit board 100 of the inventive concept, even when some small vias VS have defects such as a break SVB during a process of forming a plurality of small vias SV in contact with each via pad 120, reliable electrical connection may be provided through the other small vias SV. The traces 40 may also have these characteristics. In addition, because small vias SV have a small volume compared to general through-vias, additional small vias SV may be formed to obtain an overall volume that is similar to the overall volume of general through-vias. Since the performance of heat transfer is related to the overall volume, a decrease in the performance of heat transfer from the semiconductor chip 200 (refer to FIG. 2) may be effectively prevented thorough use of embodiments of the invention.

As described above, the printed circuit board 100 of the inventive concept is designed such that a plurality of through-vias 130 and a plurality of traces 140 are provided for one via pad 120. Thus, even when a defect occurs in any one of the through-vias 130 and/or any one of the traces 140, electrical reliability and high thermal conductivity may be guaranteed between the semiconductor chip 200 (refer to FIG. 2) and the printed circuit board 100 through use of embodiments of the invention.

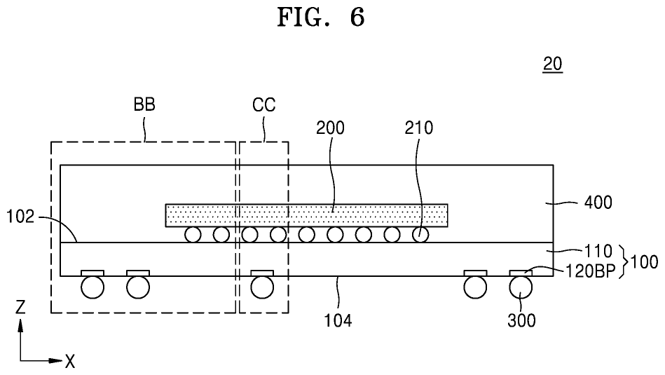

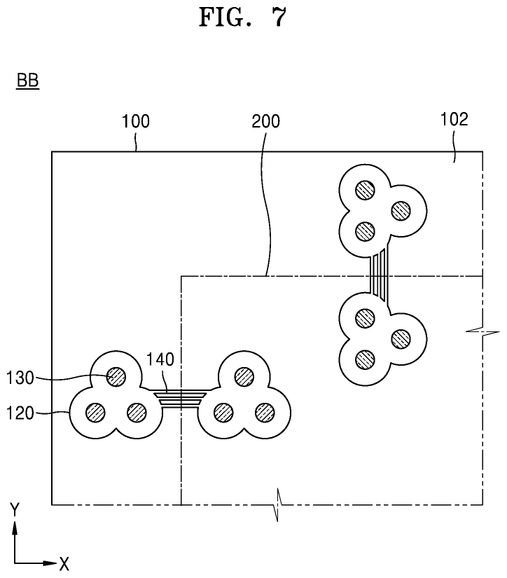

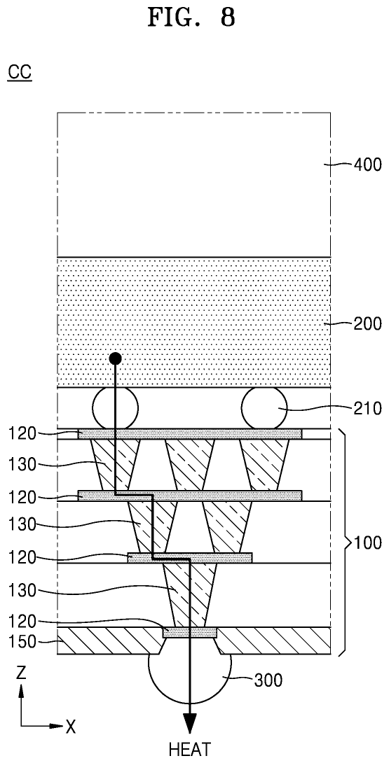

FIG. 6 is a cross-sectional view illustrating a semiconductor package 20 according to an embodiment, FIG. 7 is an enlarged plan view illustrating region BB of FIG. 6, and FIG. 8 is an enlarged cross-sectional view of region CC of FIG. 6.

Referring to FIGS. 6 to 8 together, the semiconductor package 20 includes a printed circuit board 100, a semiconductor chip 200 mounted on an upper surface 102 of the printed circuit board 100, a plurality of bumps 210 connecting the printed circuit board 100 and the semiconductor chip 200 to each other, a mold 400 covering the upper surface 102 of the printed circuit board 100 and the semiconductor chip 200, and solder balls 300 attached to a lower surface 104 of the printed circuit board 100.

The printed circuit board 100 may include a board base 110 and a plurality of solder ball pads 120BP. In addition, the printed circuit board 100 may include one or more base layers (not shown), traces 140, via pads 120 connecting the printed circuit board 100 and the bumps 210 to each other, and through-vias 130 penetrating the base layers and connecting the via pads 120 and the solder ball pads 120BP to each other.

The board base 110 may have a flat structure having an upper surface and a lower surface. The board base 110 may be formed of and/or include an epoxy resin or the like, and because the board base 110 may have a structure similar to or the same as the structure of the board base 110 shown in FIG. 3, a repeated description thereof is omitted.

The solder ball pads 120BP are formed on the lower surface of the board base 110, and the solder balls 300 are respectively attached to the solder ball pads 120BP. The solder ball pads 120BP may be electrically coupled to the traces 140 and/or the bumps 210 that may be formed on the printed circuit board 100 and may have a function of transmitting signals of the semiconductor chip 200 to the solder balls 300.

The solder ball pads 120BP may be formed at the same level as the lower surface 104 of the printed circuit board 100, but embodiments are not limited thereto. For example, in some embodiments the solder ball pads 120BP may be formed at a level lower than the lower surface 104 of the printed circuit board 100 and may thus have a protruding structure. In another example, the solder ball pads 120BP may be formed at a level higher than the lower surface 104 of the printed circuit board 100 and may thus have a buried structure.

The semiconductor chip 200 is mounted on the upper surface 102 of the printed circuit board 100. Here, like the semiconductor chip 200 described above with reference to FIG. 2, the semiconductor chip 200 may have various functions such as functions of a memory chip, a logic chip, a microprocessor, an analog device, a digital signal processor, a system-on-chip, or the like.

As shown in FIG. 6, when the semiconductor chip 200 is mounted by a flip chip method, the semiconductor chip 200 may be coupled to the printed circuit board 100 through the bumps 210. In addition, when the semiconductor package 20 is of a flip chip type, the mold 400 may be formed through a molded under fill (MUF) process. The MUF process may refer to a process of filling a gap between the semiconductor chip 200 and the printed circuit board 100 with the mold 400 instead of performing a process of filling the gap between the semiconductor chip 200 and the printed circuit board 100 with an underfill (not shown). When the mold 400 is formed through the MUF process, the exterior of the semiconductor chip 200 may be covered with the same molding member material as that used to fill the gap between the semiconductor chip 200 and the printed circuit board 100.

However, the mold 400 may not be formed through an MUF process. That is, molding may be performed by filling the gap between the semiconductor chip 200 and the printed circuit board 100 with an underfill, and then covering the exterior of the semiconductor chip 200 with a molding material. The underfill used to fill the gap between the semiconductor chip 200 and the printed circuit board 100 and the molding material used to cover the exterior of the semiconductor chip 200 may be the same or different from each other.

The printed circuit board 100 includes: the solder ball pads 120BP formed on the lower surface 104 of the printed circuit board 100; the bumps 210 attached to the upper surface 102 of the printed circuit board 100; and the traces 140 connecting the solder ball pads 120BP and the bumps 210 to each other. Although FIG. 7 illustrates that the traces 140 are exposed from the printed circuit board 100, this is for case of illustration. For example, at least some of the traces 140 may extend inside the printed circuit board 100.

Furthermore, as shown in FIG. 7, in the printed circuit board 100, the traces 140 may directly connect the via pads 120 to each other without other conductors therebetween, or may electrically connect the via pads 120 to each other with the through-vias 130 therebetween.

According to designs, at least some of the via pads 120 may have a form in which two or more sub-shapes overlap each other, and at least some of the through-vias 130 may be small vias. The through-vias 130 have an inverted pyramid shape and electrically connect the solder ball pads 120BP and the bumps 210 to each other to transfer heat generated from the semiconductor chip 200 to the solder balls 300.

As shown in FIG. 8, in some embodiments, the through-vias 130 may be designed to have an inverted pyramid shape with an end of the pyramid shape starting at the semiconductor chip 200 and an opposite end of the pyramid shape ending at a solder ball pad 120BP. For example, the through-vias 130 may be designed such that the number of through-vias 130 disposed on one via pad 120 may decrease in a vertical downward direction (negative Z direction) of the base layers.

Although not shown in FIG. 8, in other embodiments, the through-vias 130 may be designed to have a pyramid shape having a first end of the pyramid shape starting at a solder ball pad 120BP and an opposite end of the pyramid shape ending at the semiconductor chip 200. For example, the through-vias 130 may be designed such that the number of through-vias 130 disposed on one via pad 120 may increase in the vertical downward direction (negative Z direction) of the base layers.

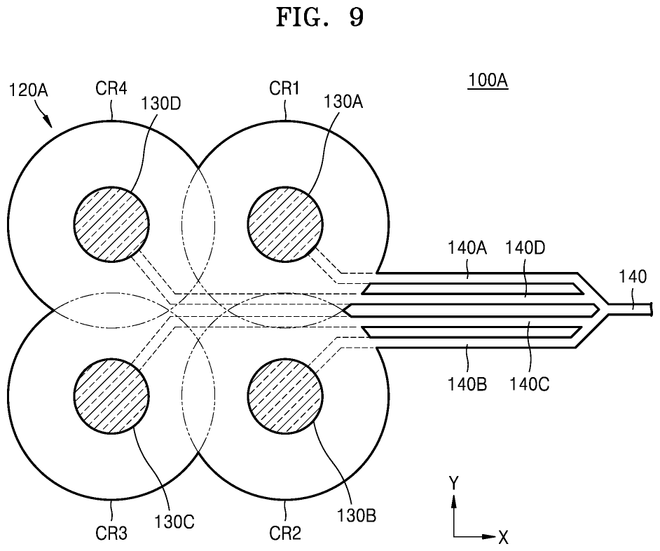

FIGS. 9 to 11 are plan views illustrating portions of printed circuit boards 100A, 100B, and 100C according to other embodiments.

Many elements of the printed circuit boards 100A, 100B, and 100C, and materials thereof may be the same as or similar to those described above with reference to FIGS. 3 to 5. Therefore, for case of description, the differences from the printed circuit board 100 described above are mainly described below.

Referring to FIG. 9, in the printed circuit board 100A of the embodiment, one via pad 120A may be designed to include four sub-shapes CR1, CR2, CR3, and CR4 having the same dimensions and arranged in a partially overlapping manner around a center point of the via pad 120A with regular angular spacing between adjacent sub-shapes (for example, each sub-shape may be congruent with one another and the angular spacing of a center point of each sub-shape from the center point of an adjacent sub-shape may be the same, such as 90° from each other in a clockwise direction).

Here, the printed circuit board 100A may be designed such that two to four through-vias 130A, 130B, 130C, and 130D may be in contact with the via pad 120A. In some embodiments, via holes may be formed respectively at center points of the sub-shapes CR1, CR2, CR3, and CR4, and the through-vias 130A, 130B, 130C, and 130D may be disposed respectively in the via holes. However, the number of sub-shapes CR1, CR2, CR3, and CR4 and the number of through-vias 130A, 130B, 130C, and 130D do not have to be equal to each other. For example, the via pad 120A may include four sub-shapes CR1, CR2, CR3, and CR4, and only two through-vias (for example, the through-vias 130A and 130B) may be in contact with the via pad 120A. In any case, one via pad 120A may be in contact with a plurality of through-vias.

In addition, the printed circuit board 100A may be designed such that four traces 140A, 140B, 140C, and 140D may be connected to one via pad 120A. In some embodiments, as many traces 140A, 140B, 140C, and 140D as the number of through-vias 130A, 130B, 130C, and 130D may be connected to one via pad 120A, and the through-vias 130A, 130B, 130C, and 130D and the traces 140A, 140B, 140C, and 140D may be matched to each other (e.g., for each through-via there is a corresponding trace). In addition, the traces 140A, 140B, 140C, and 140D may be designed to be in contact with an outer surface of the via pad 120A, and the through-vias 130A, 130B, 130C, and 130D may be matched to the traces 140A, 140B, 140C, and 140D in a 1:1 positional relationship. This is shown by dashed lines in FIG. 9.

In some embodiments, the center points of the sub-shapes CR1, CR2, CR3, and CR4 of the via pad 120A may correspond to vertices of an imaginary square, and the center point of the via pad 120A may correspond to the geometric center of the imaginary square. For example, as shown in FIG. 9, the center points of the sub-shapes CR1, CR2, CR3, and CR4 may correspond to vertices of the imaginary square.

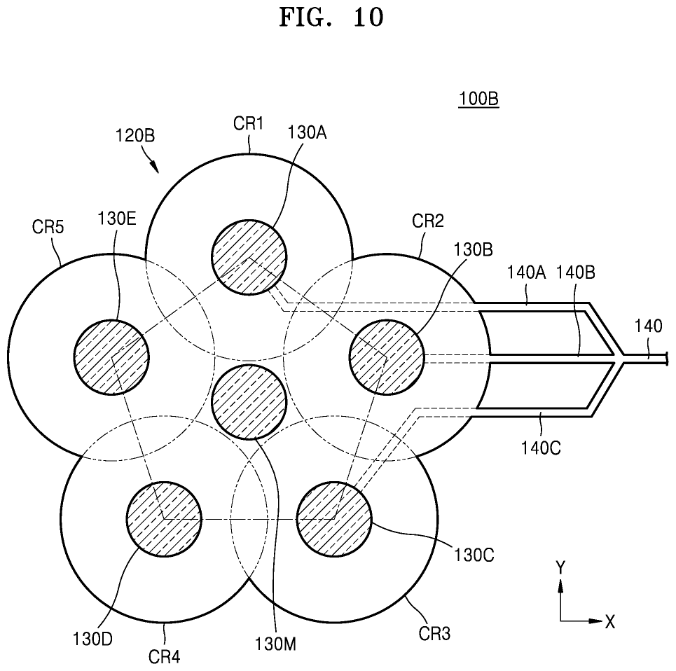

Referring to FIG. 10, in the printed circuit board 100B of the embodiment, one via pad 120B may be designed to have five sub-shapes CR1, CR2, CR3, CR4, and CR5 having substantially the same dimensions and arranged in a partially overlapping manner around a center point of the via pad 120B with regular angular spacing between adjacent sub-shapes (for example, and the angular spacing of a center point of each sub-shape from the center point of an adjacent sub-shape may be 72° from each other in a clockwise direction).

Here, the printed circuit board 100B may be designed such that two to six through-vias 130A, 130B, 130C, 130D, 130E, and 130M may be in contact with the via pad 120B. In some embodiments, via holes may be formed respectively at center points of the sub-shapes CR1, CR2, CR3, CR4, and CR5, and the through-vias 130A, 130B, 130C, 130D, 130E, and 130M may be disposed respectively at center points of the via holes and the via pad 120B. However, the number of sub-shapes CR1, CR2, CR3, CR4, and CR5 and the number of through-vias 130A, 130B, 130C, 130D, 130E, and 130M do not have to be equal to each other. For example, the via pad 120B may include five sub-shapes CR1, CR2, CR3, CR4, and CR5, and six through-vias 130A, 130B, 130C, 130D, 130E, 130M may be in contact with the via pad 120B. In any case, one via pad 120B may be in contact with a plurality of through-vias.

In some embodiments, the center points of the sub-shapes CR1, CR2, CR3, CR4, and CR5 of the via pad 120B may correspond to vertices of an imaginary regular pentagon, and the center point of the via pad 120B may correspond to a geometric center of the imaginary regular pentagon. For example, as shown in FIG. 10, the center points of the sub-shapes CR1, CR2, CR3, CR4, and CR5 may correspond to the vertices of the imaginary regular pentagon.

In some embodiments, three traces 140A, 140B, and 140C, which are fewer than the through-vias 130A, 130B, 130C, 130D, 130E, and 130M, may be connected to the via pad 120B. In this case, among the through-vias 130A, 130B, 130C, 130D, 130E, and 130M, first through-vias 130A, 130B, and 130C that are matched to the traces 140A, 140B, and 140C may be electrically conductive vias, and second through-vias 130D, 130E, and 130M that are not matched to the traces 140A, 140B, and 140C may be thermally conductive vias. However, the functions of the through-vias 130A, 130B, 130C, 130D, 130E, and 130M are not limited thereto.

In some embodiments, the through-vias 130A, 130B, 130C, 130D, 130E, and 130M may be arranged on a lower surface of the via pad 120B, and the through-vias 130A, 130B, 130C, 130D, 130E, and 130M may include one main via 130M and five sub-vias 130A, 130B, 130C, 130D, and 130E. In this case, only one through-via (not shown) extending from the main via 130M may be on an upper surface of the via pad 120B. In addition, the main via 130M may be disposed at the center point of the via pad 120B, and the sub-vias 130A, 130B, 130C, 130D, and 130E may be disposed respectively at the center points of the sub-shapes CR1, CR2, CR3, CR4, and CR5.

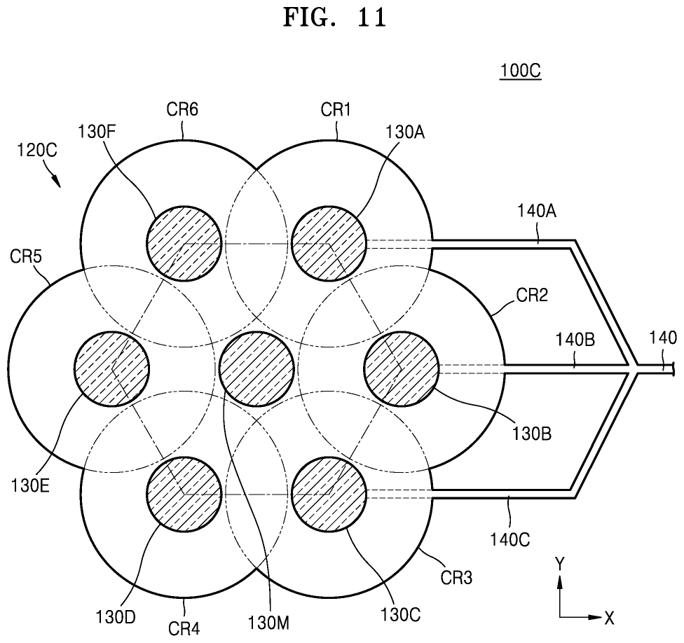

Referring to FIG. 11, in the printed circuit board 100C of the embodiment, one via pad 120C may be designed to include six sub-shapes CR1, CR2, CR3, CR4, CR5, and CR6 having substantially the same dimensions and arranged in a partially overlapping manner around a center point of the via pad 120C with regular angular spacing (for example, and the angular spacing of a center point of each sub-shape from the center point of an adjacent sub-shape may be 60° from each other in a clockwise direction).

Here, the printed circuit board 100C may be designed such that two to seven through-vias 130A, 130B, 130C, 130D, 130E, 130F, and 130M may be in contact with one via pad 120C. In some embodiments, via holes may be formed at center points of the sub-shapes CR1, CR2, CR3, CR4, CR5, and CR6, and the through-vias 130A, 130B, 130C, 130D, 130E, 130F, and 130M may be disposed respectively at center points of the via holes and the via pad 120C. However, the number of sub-shapes CR1, CR2, CR3, CR4, CR5, and CR6 and the number of through-vias 130A, 130B, 130C, 130D, 130E, 130F, and 130M do not have to be equal to each other. For example, the via pad 120C may include six sub-shapes CR1, CR2, CR3, CR4, CR5, and CR6, and seven through-vias 130A, 130B, 130C, 130D, 130E, 130F, 130M may be in contact with the via pad 120C. In any case, one via pad 120C may be in contact with a plurality of through-vias.

In some embodiments, the center points of the sub-shapes CR1, CR2, CR3, CR4, CR5, and CR6 of the via pad 120C may correspond to vertices of an imaginary regular hexagon, and the center point of the via pad 120C may be at the geometric center of the imaginary regular hexagon. For example, as shown in FIG. 11, the center points of the sub-shapes CR1, CR2, CR3, CR4, CR5, and CR6 may correspond to the vertices of the imaginary regular hexagon. This arrangement may have substantially the same shape as a honeycomb.

In some embodiments, three traces 140A, 140B, and 140C, which are fewer than the through-vias 130A, 130B, 130C, 130D, 130E, 130F, and 130M, may be connected to the via pad 120C. In this case, among the through-vias 130A, 130B, 130C, 130D, 130E, 130F, and 130M, first through-vias 130A, 130B, and 130C that are matched to the traces 140A, 140B, and 140C may be electrically conductive vias, and second through-vias 130D, 130E, 130F, and 130M that are not matched to the traces 140A, 140B, and 140C may be thermally conductive vias. However, the functions of the through-vias 130A, 130B, 130C, 130D, 130E, 130F, and 130M are not limited thereto.

In some embodiments, the through-vias 130A, 130B, 130C, 130D, 130E, 130F, and 130M may be disposed on a lower surface of the via pad 120C, and the through-vias 130A, 130B, 130C, 130D, 130E, 130F, and 130M may include a main via 130M and six sub-vias 130A, 130B, 130C, 130D, 130E, and 130F. In this case, only one through-via (not shown) extending from the main via 130M may be disposed on an upper surface of the via pad 120C. In addition, the main via 130M may be disposed at the center point of the via pad 120C, and the sub-vias 130A, 130B, 130C, 130D, 130E, and 130F may be disposed at the center points of the sub-shapes CR1, CR2, CR3, CR4, CR5, and CR6.

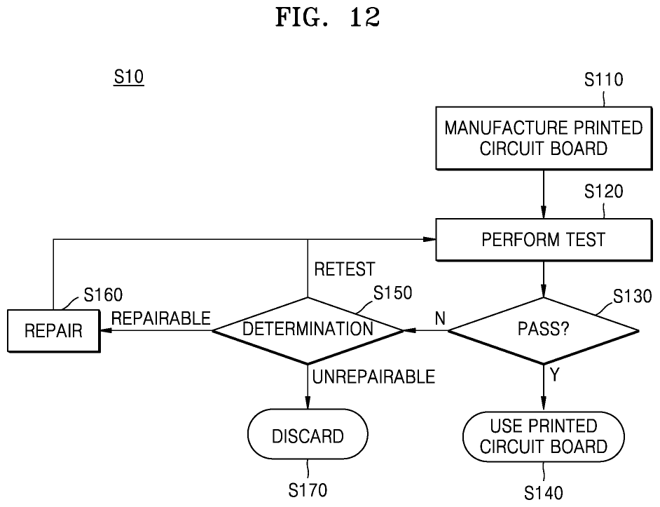

FIG. 12 is a flowchart illustrating a printed circuit board test process S10 according to an embodiment.

Referring to FIG. 12, the printed circuit board test process S10 may include first to seventh operations S110 to S170.

In other embodiments, some operations may be performed in an order that is different from the order described below. For example, two operations described in succession may be performed substantially at the same time or in reverse order to the described order.

A first operation S110 of manufacturing a printed circuit board may be performed. For example, in a process of manufacturing a printed circuit board, a large-area printed circuit board module is prepared. Next, a plurality of semiconductor chips are mounted in a plurality of mounting regions on an upper surface of the large-region printed circuit board module, and a mold is formed to cover the semiconductor chips. Next, a plurality of solder balls are attached to a plurality of ball lands provided on a lower surface of the large-area printed circuit board module. The large-area printed circuit board module on which the semiconductor chips and the solder balls are provided as described above is cut into predetermined sizes along cutting lines to separate individual printed circuit boards.

A second operation S120 is performed to test each of the printed circuit boards. The printed circuit boards are tested by testing each of the printed circuit boards using an analysis device. In some embodiments, a plurality of printed circuit boards may be simultaneously tested. Results of the testing of each of the printed circuit boards may be transmitted to a test server.

A third operation S130 is performed to determine whether test results are acceptable. In a fourth operation S140, each printed circuit board that has passed the test (indicated by Y) is used in a semiconductor package, and the printed circuit board test process S10 ends. Printed circuit boards that have passed the test (indicated by Y) may be used in semiconductor packages and may then be supplied to the market. However, each printed circuit board that has not passed the test (indicated by N) is evaluated in a fifth operation S150. It is determined whether to retest or repair each printed circuit board that has not passed the test (indicated by N).

This determination may be performed by analyzing test results. For example, when a defect relating to the electrical reliability of a printed circuit board is suspected or results of the test of a printed circuit board are not clear, the printed circuit board may be retested.

When it is determined, based on test results, that a printed circuit board is repairable, the printed circuit board may be repaired in a sixth operation S160 and then be retested. However, a printed circuit board that is determined to be unrepairable or does not pass the retest is discarded in a seventh operation S170, and the printed circuit board test process S10 ends.

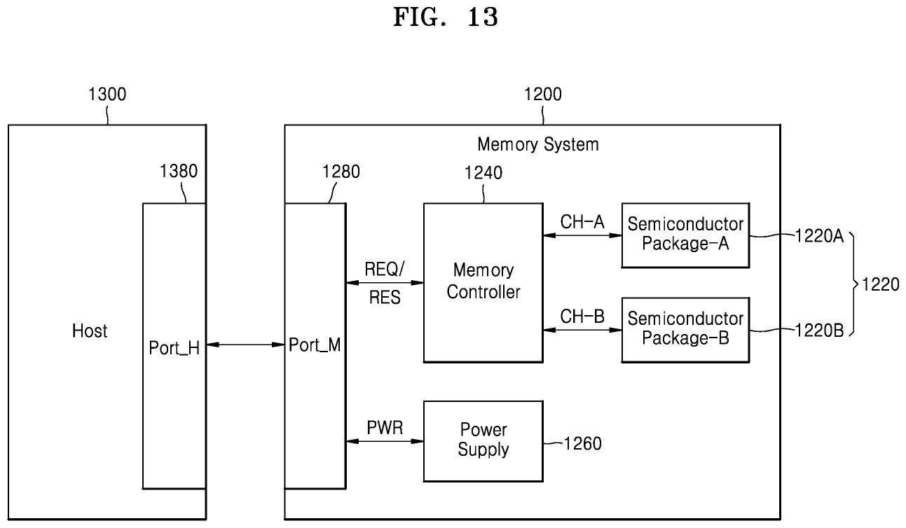

FIG. 13 is a block diagram illustrating a removable storage device 1200.

Referring to FIG. 13, the removable storage device 1200 may communicate with a host 1300 and may include semiconductor packages 1220, a memory controller 1240, a power supply 1260, and a first port 1280.

The semiconductor packages 1220 may include a plurality of memory chips each including a plurality of memory cells. Here, the semiconductor packages 1220 refer to a concept including all cases in which memory chips are provided in a chip scale form instead of a package form. That is, the semiconductor packages 1220 do not refer to only general semiconductor packages.

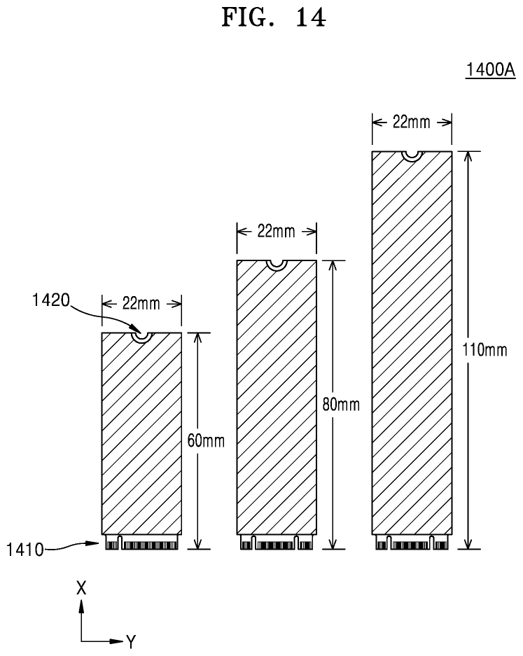

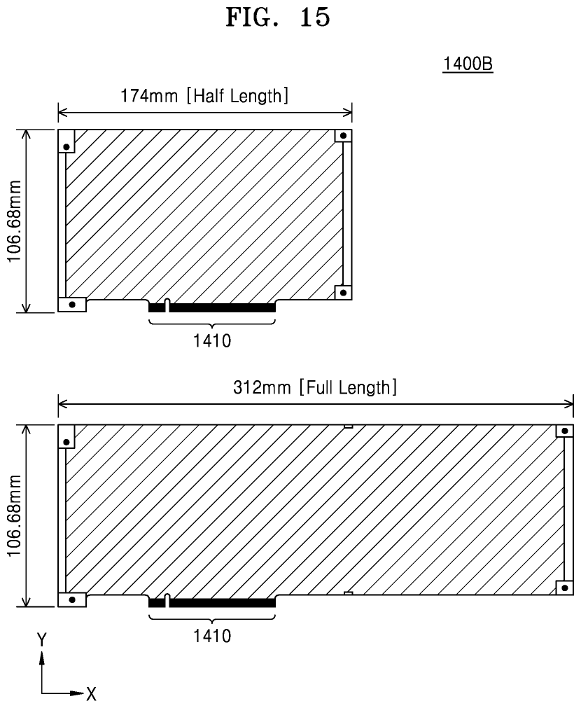

Owing to advances in semiconductor packaging processes, the memory chips may be mounted on a printed circuit board (refer to printed circuit boards 1400A and 1400B shown in FIGS. 14 and 15) in a chip scale form instead of a package form. For example, the memory chips may be entirely protected by a case or the like or may be encapsulated directly on a printed circuit board (refer to the printed circuit boards 1400A and 1400B shown in FIGS. 14 and 15) using a polymer resin rather than a molding compound.

For example, the memory chips may each include a 3D memory cell array. The 3D memory cell array may be monolithically formed in an active region of a silicon wafer with at least one physical level of memory cells that include a circuit related to operations thereof and are formed on or in the silicon wafer. The term “monolithically” may indicate that layers of a memory cell array that have different levels are stacked in such a manner that each layer may be on top of a lower layer in the memory cell array.

In some embodiments, the 3D memory cell array may include a vertical NAND string in which at least one memory cell is vertically disposed above another memory cell, and auxiliary cells are disposed above or below the memory cells. In this case, at least one memory cell of the 3D memory cell array may include a charge trap layer.

In other embodiments, the memory cells may be planar NAND flash memory cells having a horizontal 2D structure. In other embodiments, the memory cells may be nonvolatile memory cells such as RRAM cells, PRAM cells, or MRAM cells.

Memory cells included in the memory cell array may each store 2 or more-bit data. In some embodiments, memory cells included in the memory cell array may each be a multi-level cell (MLC) capable of storing 2-bit data. In other embodiments, memory cells included in the memory cell array may each be a triple level cell (TLC) capable of storing 3-bit data. In other embodiments, memory cells included in the memory cell array may each store 4 or more-bit data. In addition, memory cells included in a string of the memory cell array may each be used as a single level cell (SLC) that stores 1-bit data.

The memory chips of the semiconductor packages 1220 may be connected to the memory controller 1240 through channel groups. For example, a semiconductor package-A 1220A may be connected to the memory controller 1240 through a channel group CH-A, and a semiconductor package-B 1220B may be connected to the memory controller 1240 through a channel group CH-B.

Although FIG. 13 illustrates two semiconductor packages 1220A and 1220B and two channel groups CH-A and CH-B, embodiments are not limited thereto. For example, the removable storage device 1200 of the inventive concept may include one semiconductor package and one channel group, or may include three or more semiconductor packages and three or more channel groups.

The memory controller 1240 may receive a request REQ from the host 1300 through the first port 1280 and transmit a response RES to the host 1300 through the first port 1280. For example, the memory controller 1240 may receive a data read request from the host 1300 through the first port 1280, and in response to the data read request, the memory controller 1240 may read data stored in the memory chips of the semiconductor packages 1220 and transmit the data to the host 1300 through the first port 1280.

The power supply 1260 may receive power PWR from the host 1300 through the first port 1280, and based on the received power PWR, the power supply 1260 may supply power to components of the removable storage device 1200 such as the semiconductor packages 1220 and the memory controller 1240.

The first port 1280 may include a plurality of pins and may be connected to a second port 1380 of the host 1300. The number, size, and arrangement of pins of the first port 1280 and the second port 1380 may be determined based on an interface protocol used for communication with the host 1300. For example, the removable storage device 1200 and the host 1300 may communicate with each other based on at least one of various interface protocols such as Universal Serial Bus (USB), Multimedia Card (MMC), Peripheral Component Interconnect Express (PCI-E), Advanced Technology Attachment (ATA), Serial-ATA, Parallel-ATA, Small Computer System Interface (SCSI), Enhanced Small Disk Interface (ESDI), and Integrated Drive Electronics (IDE), and the first port 1280 may include a plurality of pins according to such interface protocols.

The removable storage device 1200 may have various form factors such that semiconductor packages (for example, the semiconductor packages 1220) having various storage capacities may be mounted on the removable storage device 1200. The removable storage device 1200 may include a package board such as the printed circuit boards 1400A and 1400B (refer to FIGS. 14 and 15), and the semiconductor packages 1220, the memory controller 1240, and the power supply 1260, which are components of the removable storage device 1200, may be mounted on the printed circuit board 1400A or 1400B (refer to FIGS. 14 and 15).

The printed circuit boards 1400A and 1400B (refer to FIGS. 14 and 15) may each include memory chip mounting regions that are apart from each other. Depending on an environment or application in which the removable storage device 1200 is used, the semiconductor packages 1220 may be mounted in all of the memory chip mounting regions or only one of the memory chip mounting regions, thereby adjusting the memory capacity of the removable storage device 1200 and increase the flexibility of the removable storage device 1200.

FIGS. 14 and 15 are views illustrating examples of various form factors specifying printed circuit boards that are usable in the removable storage device 1200 shown in FIG. 13.

For example, FIG. 14 illustrates various sizes of the printed circuit board 1400A according to the M.2 standard, and FIG. 15 illustrates various sizes of the printed circuit board 1400B according to a PCI card standard.

Referring to FIG. 14, the M.2 standard specifying examples of form factors may define the thickness and left-right width of the printed circuit board 1400A of the storage device 1200 (refer to FIG. 13).

The M.2 standard may define the length of the printed circuit board 1400A as 60 mm, 80 mm, or 110 mm in a first horizontal direction (X direction), and as 22 mm in a second horizontal direction (Y direction).

The M.2 standard may define a port 1410. The port 1410 may be provided on a side of the printed circuit board 1400A and may include a plurality of pins for communication with the host 1300 (refer to FIG. 13). The pins may be exposed patterns, and the exposed patterns may be connected to a socket of the host 1300 (refer to FIG. 13). The pins may include a conductive material, for example a metal such as copper.

In addition, the M.2 standard may define a recessed structure 1420 for mounting and fixing the removable storage device 1200 (refer to FIG. 13) to the host 1300 (refer to FIG. 13). The form factors may include a semicircular recessed structure 1420 formed on another side of the printed circuit board 1400A that is opposite the port 1410. The exposed patterns may be formed on an edge of the recessed structure 1420, and when the printed circuit board 1400A is attached to the host 1300, the exposed patterns may be connected to a conductor of the host 1300. For example, the exposed patterns formed on an edge of the recessed structure 1420 may correspond to a ground node of the removable storage device 1200 (refer to FIG. 13), and when the printed circuit board 1400A is attached to the host 1300, the exposed patterns may be connected to a conductor corresponding to a ground node of the host 1300.

Referring to FIG. 15, the PCI card standard specifying examples of form factors may define the length of the printed circuit board 1400B of the storage device 1200 (refer to FIG. 13) as 106.68 mm in a second horizontal direction (Y direction) and as 174 mm or 312 mm in a first horizontal direction (X direction).

The length defined in the first horizontal direction (X direction) by the PCI card standard may be the maximum length of the printed circuit board 1400B. In this case, the length of 174 mm that is defined in the first horizontal direction (X direction) may be referred to as a half-length, and the length of 312 mm that is defined in the first horizontal direction (X direction) may be referred to as a full-length. For example, when the printed circuit board 1400B has the half-length, the printed circuit board 1400B may have a length of 106.68 mm in the second horizontal direction (Y direction) and a length of 174 mm or less in the first horizontal direction (X direction). With respect to the half-length and the full-length, a port 1410 may have the same position and shape.

The printed circuit boards 1400A and 1400B may have various form factors according to the number of semiconductor packages determined based on different specifications and memory capacities of various main boards of electronic apparatuses.

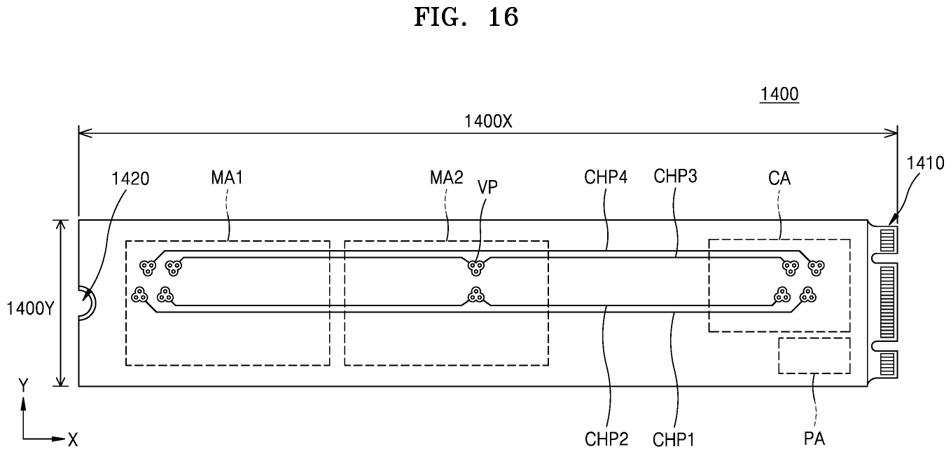

FIG. 16 is a plan view illustrating a printed circuit board 1400 according to another embodiment.

Referring to FIG. 16, the printed circuit board 1400 includes a plurality of channel patterns such as first to fourth channel patterns CHP1, CHP2, CHP3, and CHP4 for writing and reading operations.

The printed circuit board 1400 is for mounting semiconductor packages thereon and includes a base layer and a wiring portion. The wiring portion includes: via pads VP and traces (not shown) that are formed on the base layer; and through-vias (not shown) that penetrate the base layer and are connected to the via pads VP.

In some embodiments, a semiconductor package may be electrically connected to the first to fourth channel patterns CHP1, CHP2, CHP3, and CHP4 in a first mounting region MA1, and a semiconductor package may be electrically connected to the second and third channel patterns CHP2 and CHP3 in a second mounting region MA2.

In addition, the printed circuit board 1400 may include a power supply region PA adjacent to a memory controller region CA. However, the arrangement of the power supply region PA is not limited thereto.

In embodiments, the via pads VP may be formed for electrical connection of the first to fourth channel patterns CHP1, CHP2, CHP3, and CHP4. As described above, the via pads VP may be designed such that N sub-shapes (N refers to an integer greater than 1) having the same dimensions may be arranged around a center point of each of the via pads VP with regular angular spacing (for example, and the angular spacing of a center point of each sub-shape from the center point of an adjacent sub-shape may be 120° from each other in a clockwise direction) in a partially overlapping manner.

A length 1400X of the printed circuit board 1400 in a first horizontal direction (X direction) may be 60 mm, 80 mm, or 110 mm, and a length 1400Y of the printed circuit board 1400 in a second horizontal direction (Y direction) may be 22 mm. That is, the printed circuit board 1400 may be formed according to the M.2 standard described above, but embodiments are not limited thereto.

While the inventive concept has been particularly shown and described with reference to embodiments thereof, it will be understood that various changes in form and details may be made therein without departing from the spirit and scope of the following claims.

What is claimed is:

1. A printed circuit board comprising:
base layers stacked in a vertical direction from a lowermost layer to an uppermost layer;
traces disposed on a first base layer among the base layers;
via pads with each via pad respectively disposed on a respective base layer of the base layers and electrically connected to the traces; and
through-vias with each through-via extending in the vertical direction through a respective base layer of the base layers to electrically connect a respective first via pad of the via pads to a respective second via pad of the via pads, wherein the respective first via pad and the respective second via pad are positioned at different vertical levels,
wherein each via pad of the via pads has a shape comprising at least two sub-shapes having the same dimensions and that are arranged around a center point of a respective via pad in a partially overlapping manner with regular angular spacing between adjacent sub-shapes, and
wherein each of the via pads is in contact with at least two of the respective through-vias.

2. The printed circuit board of claim 1, wherein a via hole is formed at each center point of at least two of the sub-shapes, and
the through-vias are each respectively disposed in a respective via hole.

3. The printed circuit board of claim 1, wherein a first via pad among the via pads is connected to at least two traces among the traces.

4. The printed circuit board of claim 3, wherein the first via pad is connected to the same number of traces as the number of through-vias that are connected to the first via pad, and
the through-vias and the traces are matched to each other.

5. The printed circuit board of claim 3, wherein the number of traces connected to the first via pad is less than the number of through-vias connected to the first via pad,
the through-vias include first through-vias that are matched to the traces and are electrically conductive vias, and
the through-vias include second through-vias that are not matched to the traces and are thermally conductive vias.

6. The printed circuit board of claim 1, wherein center points of each sub-shape of the at least two sub-shapes of each of the via pads correspond to vertices of an imaginary regular N-polygon, and
the center point of the via pad corresponds to the geometric center of the imaginary regular N-polygon.

7. The printed circuit board of claim 1, wherein at least two through-vias are disposed on a lower surface of a first via pad among the via pads and the at least two through-vias comprise a main via and sub-vias that are through-vias other than the main via, and
only one through-via of the at least two through-vias is disposed on an upper surface of the via pad and extends from the main via.

8. The printed circuit board of claim 7, wherein the main via is disposed at the center point of the via pad, and
the sub-vias are disposed respectively at center points of the sub-shapes.

9. The printed circuit board of claim 1, wherein a number of through-vias disposed on a respective via pad decreases in a vertical downward direction of the base layers.

10. The printed circuit board of claim 1, wherein each of the through-vias has a diameter of about 10 μm or less, and
the via pads have a maximum diameter within a range of 10 μm to 50 μm.

11. A printed circuit board comprising:
a board base comprising a plurality of base layers;
a plurality of via pads with a via pad being disposed on each of the plurality of base layers; and
a plurality of through-vias with at least one respective through-via of the plurality of through-vias penetrating a respective base layer and making contact with a respective via pad of the plurality of base layers,
wherein each via pad of the plurality of via pads has a shape in which a plurality of sub-shapes are arranged based on a center point of the respective via pad in a partially overlapping manner, and a group of through-vias are in contact with the respective via pad in a manner corresponding to the plurality of sub-shapes.

12. The printed circuit board of claim 11, wherein a plurality of traces are connected to a first via pad of the plurality of via pads, and
through-vias of the plurality of through-vias that are connected to the via pad and the plurality of traces are matched to each other.

13. The printed circuit board of claim 12, wherein the plurality of traces are connected to each other in a region outside the first via pad.

14. The printed circuit board of claim 11, wherein some of the plurality of through-vias are electrically conductive vias, and other through-vias are thermally conductive vias.

15. The printed circuit board of claim 11, wherein among the plurality of through-vias, each through-via disposed at a center point of a respective via pad extends upward through a respective base layer of the plurality of base layers in a vertical direction.

16. A semiconductor package comprising:
a printed circuit board comprising a chip mounting region and a peripheral region planarly surrounding the chip mounting region;
a semiconductor chip having first and second surfaces facing each other and comprising a chip pad disposed on the first surface, the semiconductor chip being mounted in the chip mounting region with the first surface facing an upper surface of the printed circuit board; and
a connection member attached to the chip pad,
wherein the printed circuit board comprises:
a plurality of base layers;
via pads with each via pad respectively disposed on a respective base layer of the plurality of base layers and electrically connected to a plurality of traces; and
through-vias extending in a vertical direction with each of the through-vias extending through a respective base layer of the plurality of base layers to electrically connect the via pads positioned at different vertical levels,
wherein each of the via pads has a shape in which at least two sub-shapes have the same diameter and are arranged around the center point of the via pad in a partially overlapping manner with regular angular spacing between adjacent sub-shapes, and
each of the via pads are in contact with at least two respective through-vias.

17. The semiconductor package of claim 16, wherein a first via pad of the via pads is provided on an uppermost layer of the plurality of base layers is in contact with the connection member, and
a number of through-vias disposed on each via pad decreases in a vertical downward direction of the plurality of base layers.

18. The semiconductor package of claim 17, wherein among the through-vias, a respective through-via disposed at a center point of each of the via pads extends upward through a respective base layer of the plurality of base layers in the vertical direction.

19. The semiconductor package of claim 16, wherein the number of traces connected to a first via pad among the via pads is less that the number of through-vias connected to the first via pad,
the through-vias connected to the first via pad include first through-vias that are matched to the plurality of traces and are electrically conductive vias, and
the through-vias connected to the via pad include, second through-vias that are not matched to the plurality of traces and are thermally conductive vias.

20. The semiconductor package of claim 16, wherein each of the through-vias has a diameter of about 10 μm or less, and
the via pads have a maximum diameter within a range of about 10 μm to about 50 μm.
